(19) United States
(12) Patent Application Publication
(10) Pub. No.: US 2026/0149892 A1
(43) Pub. Date: May 28, 2026

(54) Cryogenic Thermal Imager

(71) Applicant: Brown University, Providence, RI (US)

(72) Inventors: Jacob Rosenstein, Providence, RI (US); Pradeep Guduru, Providence, RI (US); Xiaoyu Lian, Atlanta, GA (US)

(21) Appl. No.: 19/399,447

(22) Filed: Nov. 24, 2025

Related U.S. Application Data
(60) Provisional application No. 63/724,076, filed on Nov. 22, 2024.

(51) Int. Cl. H04N 25/21; H04N 25/771; H04N 25/78; H05K 7/20

(52) U.S. Cl. CPC H04N 25/21; H04N 25/771; H04N 25/78; H05K 7/20372

(57) ABSTRACT

A high-speed global-shutter thermal imaging system includes a cryostat, the cryostat including a store of coolant and a detector assembly, a vacuum pump, and an output channel to a analog-to-digital converter (ADC).

### CROSS-REFERENCE TO RELATED APPLICATION

The present application claims priority benefit of U.S. Provisional Application No. 63/724,076, filed Nov. 22, 2024, which is herein incorporated by reference in its entirety.

### TECHNICAL FIELD

The present disclosure relates to imaging, and more particularly to a cryogenic thermal imaging and a cryogenic thermal imaging design, system and apparatus.

### BACKGROUND

In general, high-speed thermal imaging is an essential tool for many industrial and scientific applications. However, while complex thermal phenomena can occur on the microsecond timescales, even the fastest commercial thermal cameras can generally acquire only thousands of frames per second. Previous demonstrations at visible wavelengths using specialized burst image sensors have achieved millions of frames per second, but these speeds have generally remained inaccessible for thermal infrared imaging. This limitation comes from the fact that high-performance photodetectors for mid- and long-wavelength infrared (IR) must be constructed from low-bandgap semiconductors, and these devices must operate at very low temperatures. Thus, thermal IR imaging is not compatible with integrated silicon photodetectors, and cryogenic operation presents practical challenges for scaling up nonintegrated implementations.

### SUMMARY

The following presents a simplified summary of the innovation in order to provide a basic understanding of some aspects of the invention. This summary is not an extensive overview of the invention. It is intended to neither identify key or critical elements of the invention nor delineate the scope of the invention. Its sole purpose is to present some concepts of the invention in a simplified form as a prelude to the more detailed description that is presented later.

In an aspect, the present invention features system including a cryostat, the cryostat including a store of coolant and a detector assembly, a vacuum pump, and an output channel to a analog-to-digital converter (ADC).

In another aspect, the present invention features a system including a cryostat, the cryostat including a store of liquid nitrogen and a detector assembly positioned within the cryostat behind an Zinc selenide (ZnSe) window, a vacuum pump, and an output channel to a analog-to-digital converter (ADC).

Embodiments may have one or more of the following advantages.

The system is designed for cryogenic operation at liquid nitrogen temperatures, and it achieves a maximum burst-mode frame rate of five million frames per second, which is the fastest demonstrated imaging array for mid/long-wavelength infrared.

The system is a high-speed global-shutter thermal imaging system with a 24V×24H pixel HgCdTe infrared focal plane array (FPA) detector and a custom complementary metal-oxide semiconductor (“CMOS”) readout integrated circuit (ROIC), including a 768-frame on-chip analog burst memory bank. Each pixel contains a buffered current injection circuit and a background current reduction circuit.

The high-speed global-shutter burst-mode thermal imaging system is optimized for mid- and long-wavelength infrared light (3-10 μm). This is made possible by pairing a custom CMOS readout integrated circuit (ROIC) with a mercury cadmium telluride (MCT or HgCdTe) photodiode array.

The system achieves thermal imaging burst frame rates as fast as five million frames per second, storing a maximum of 768 frames (153.6 us at five million frames per second).

### BRIEF DESCRIPTION OF DRAWINGS

The patent or application file contains at least one drawing executed in color. Copies of this patent or patent application publication with color drawing(s) will be provided by the Office upon request and payment of the necessary fee. The foregoing and other features and advantages of the present embodiments will be more fully understood from the following detailed description of illustrative embodiments taken in conjunction with the accompanying drawings in which:

FIGS. 1A, 1B and 1C illustrate one embodiment of an exemplary high-speed global-shutter burst-mode thermal imaging system.

FIGS. 2A, 2B, 2C, 2D, 2E and 2F illustrate exemplary diagrams of one embodiment of a readout integrated circuit (ROIC).

FIGS. 3A, 3B and 3C illustrate dark current subtraction.

FIG. 4 illustrates an exemplary experimental cryostat setup.

FIG. 5A is an exemplary graph.

FIG. 5B illustrates experimental responses.

FIGS. 6A and 6B illustrate spatio-temporal infrared imaging at five million frames per second.

FIG. 6C illustrates image frames before and after a laser line was revealed.

FIG. 6D illustrates a leading edge of the revealed laser line moving at 79.5 μm/μs.

FIG. 7 is a table.

FIG. 8 is a table.

FIGS. 9A-9B illustrate an exemplary high-speed global-shutter burst-mode thermal imaging system.

FIGS. 10A-10E illustrate exemplary diagrams of a readout integrated circuit (ROIC).

FIG. 11 illustrates an exemplary memory cell.

FIGS. 12A-12C illustrate example compression logic.

FIGS. 13A-13C illustrate exemplary spatial compression.

FIGS. 14A-14C illustrate exemplary temporal compression.

FIGS. 15A-15B illustrate exemplary compression sensing reconstruction.

FIG. 16 is a table.

FIG. 17 depicts an experimental cryostat setup.

### DETAILED DESCRIPTION

It is to be understood that the specific devices and processes illustrated in the attached drawings and described in the following specification are exemplary embodiments of the inventive concepts defined in the appended claims. Hence, specific dimensions and other physical characteristics relating to the embodiments disclosed herein are not to be considered as limiting, unless the claims expressly state otherwise.

The present invention described herein is a high-speed global-shutter burst-mode thermal imaging system which is optimized for mid- and long-wavelength infrared light (3-10 μm). This is made possible by pairing a custom complementary metal-oxide semiconductor (CMOS) readout integrated circuit (ROIC) with a mercury cadmium telluride (MCT or HgCdTe) photodiode array. HgCdTe photodetectors can have excellent infrared sensitivity, but their small bandgap means that active cooling is needed to optimize the noise and dark current. Thus, the imaging system is designed to operate within a liquid nitrogen cryostat, at approximately −196° C. (77° K). To minimize wiring overhead and parasitic capacitances, the imaging system is designed with CMOS ROIC to interface directly with the FPA inside the cryostat. In general, a cryostat is a vacuum insulated sample environment that uses liquid cryogens, such as nitrogen or helium, or a mechanical cooler to cool the temperature of a sample.

### Example I

### Thermal Imaging System with a First Embodiment of a Read Out Integrated Circuit

According to one aspect, a thermal imaging system is provided with a focal plane array bonded to a first embodiment of a custom read out integrated circuit each of which are within a cryostat and placed behind an optical window through which infrared laser light is to be transmitted. Such a first embodiment of a thermal imaging system achieves thermal imaging burst frame rates as fast as five million frames per second, storing a maximum of 768 frames (153.6 μs at five million frames per second). The focal plane array (FPA) has a 24×24 pixel array at a 30-micron pitch in a common-cathode arrangement. The pixel pitch is close to the diffraction-limited resolution for the Long-Wave Infrared (LWIR) focusing optics, and the FPA and ROIC memory bank are sized to capture dynamic failure events within solid materials, such as transient shear band formation.

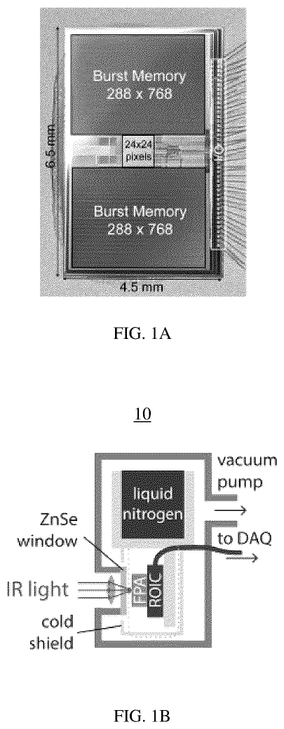

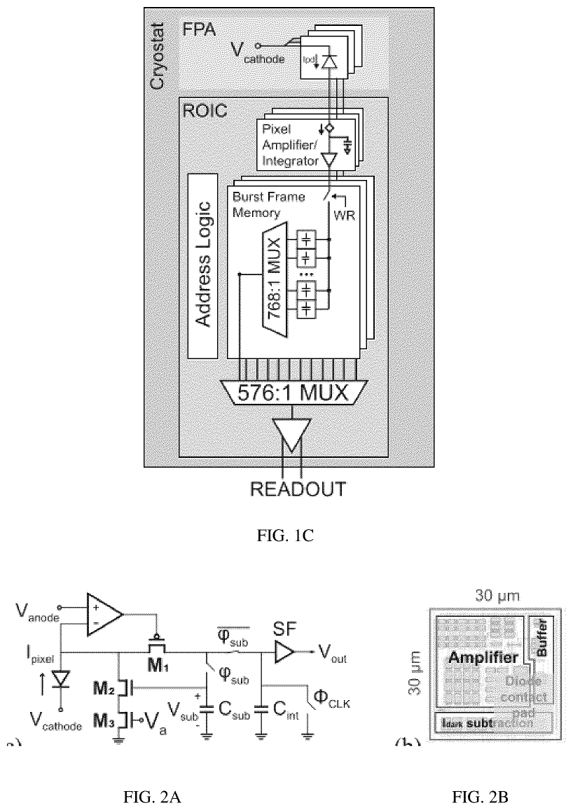

Referring now to FIGS. 1A, 1B and 1C, an exemplary high-speed global-shutter burst-mode thermal imaging system illustrated. FIG. 1A illustrates an exemplary die photo of the custom cryogenic CMOS ROIC for infrared imaging. FIG. 1B is an illustration of the imaging system 10. An infrared FPA is bump-bonded to the ROIC, and the detector assembly is positioned within a liquid nitrogen cryostat behind an optical window. FIG. 1C illustrates an architectural diagram of the signal paths within the ROIC supporting high speed burst imaging.

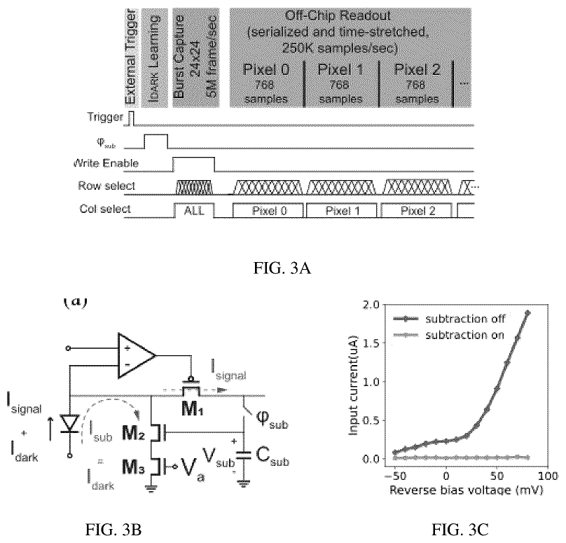

The CMOS ROIC has an architecture to support image acquisition at millions of frames per second. To directly digitize five million frames per second for all 576 pixels would imply a digitization bandwidth of 2.9 GS/s, but since the ROIC is positioned within a cryostat, there are constraints on the system's size, wiring, bandwidth, and power dissipation. Therefore, instead of real-time digitization, the ROIC is designed with on-chip analog burst memory banks. A simplified illustration of the overall ROIC data path is shown in FIG. 1C, and an illustration of the acquisition sequence is shown in FIG. 3A. The photocurrent from each pixel is amplified, and bursts of samples are written in parallel to the capacitive memory banks. The stored frames are later read out serially from the chip at a reduced speed. Compared to the on-chip real-time burst write speed, the readout is serialized and time-stretched by several orders of magnitude.

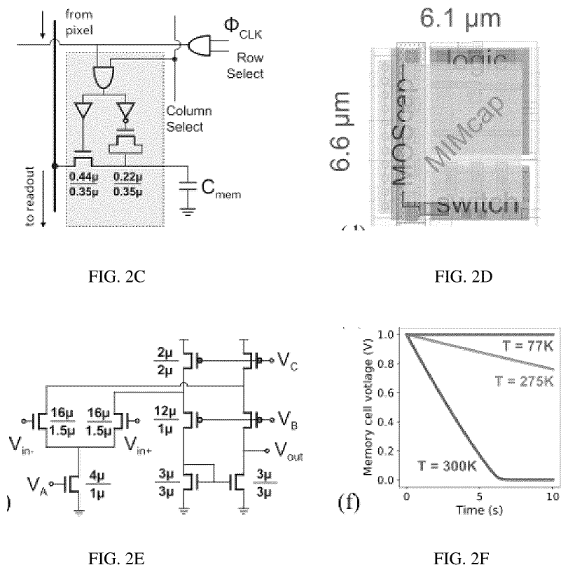

In FIGS. 2A, 2B, 2C, 2D, 2E and 2F, exemplary diagrams of the ROIC are illustrated. More specifically, FIG. 2A illustrates a pixel cell schematic and FIG. 2B illustrates a pixel layout, including the flip-chip photodiode contact pad. The ROIC has 576 pixel amplifiers. FIG. 2C illustrates a memory cell schematic and FIG. 2D illustrates a memory cell layout. The ROIC has a total of 442,368 memory cells to support up to 768 frame burst captures. FIG. 2E is a schematic of the amplifier used in pixels and FIG. 2F illustrates simulated memory cell leakage from room temperature (300° K) to liquid nitrogen temperature (77° K).

FIGS. 3A, 3B and 3C illustrate dark current subtraction. More specifically, FIG. 3A illustrates a summary of the overall timing for burst acquisition and serialized readout. FIG. 3B illustrates how the preamplifier is placed in feedback to memorize the dark current in the learning phase. FIG. 3C illustrates how the subtraction circuit removes dark current and ambient background signal.

Each pixel in the ROIC contains an integrating preamplifier, dark current subtraction circuit and output buffer as shown in FIG. 2A. One benefit of the hybrid FPA/ROIC assembly is that we can achieve a high optical fill factor while still having area within each pixel for signal conditioning circuits.

The photocurrent is acquired with a high-speed buffered direct injection (BDI) circuit, which buffers the photocurrent during the brief exposure time and regulates the photodiode anode to maintain a constant reverse bias (typically 50 mV). The amplifier is implemented with a folded structure as shown in FIG. 2E. The common-mode voltage is held above 1.5 V in order to keep M1 in saturation while the signal current is integrated onto Cᵢₙₜ. The source follower is designed to buffer the integrated voltage into the pixel's burst memory cells, with a bandwidth >50 MHz. The BDI current buffer has a bandwidth >200 MHz and consumes 216 μW, while the source follower takes 35 μW in each pixel.

Even at low temperatures, HgCdTe photodiodes can have relatively large reverse leakage currents, and their dark current can vary significantly as a function of temperature, experimental conditions, and device variation. To help tolerate this leakage current, the ROIC implements an adaptive subtraction circuit, which “memorizes” the experimental dark current in each pixel in the moments before the signal acquisition. The system is designed to acquire burst videos of brief transient high-temperature events, and thus the time shortly before the burst capture can provide an useful quiescent background.

Initially, V_{sub}=0, both M2 and M3 [FIG. 2A] are off, and Iₚᵢₓₑₗ is dominated by the dark current (I_{dark}). During the background learning phase, φ_{sub}=1, and the pixel current is directed to charge up a small capacitor (C_{sub}=193 f_{F}), whose voltage increases until I_{sub}=I_{dark}. M3 is maintained in the linear region, serving as a degeneration resistance on M2, and the bias value of Vₐ determines the upper limit of the subtraction current range. Dummy switches are used to minimize the charge injection on C_{sub}. Since the transient burst capture lasts less than 160 μs, and the ROIC is operated at cryogenic temperature, the leakage from C_{sub} is not significant.

When the pixel transitions to its active phase [φ_{sub}=0, FIG. 3B], V_{sub} stays unchanged, and I_{sub} continues to represent the memorized dark current. During burst image acquisition, I_{signal} thus represents changes in the photodiode currents compared to the memorized background current (I_{signal}=Iₚᵢₓₑₗ−I_{sub}), which can help to increase the useful dynamic range. An experimental measurement of the input-referred signals from one pixel with/without the background subtraction is shown in FIG. 3C, as a function of reverse bias voltage.

Based on the FPA pixel area, optical magnification, and models of the 3-10 μm thermal emissions, the integration capacitor was selected to be Cᵢₙₜ=750 fF. The pixel integration time (shutter speed) per frame is programmable, with typical values of 75-125 ns. At the end of each integration period, the integrated output voltage from each pixel is sampled into the memory bank. No mechanical shutter is required during the recording.

The on-chip frame memory is implemented as a series of capacitor banks as shown in FIG. 2C. Each memory cell has Cₘₑₘ=32.6 f_{F} plus switches and logic within 6.61 μm×6.1 μm, and there are 768 cells available for each pixel. Thick-oxide devices were used as switches to minimize leakage, while dummy switches were implemented to reduce the charge injection. Despite the small capacitances, the low-temperature operation mitigates concerns about charge leakage. Representative leakage simulations are presented in FIG. 2F, showing that while the leakage would be significant at room temperature, at liquid nitrogen temperatures the leakage is dramatically reduced. After an experimental burst capture, the memory bank can be read out in a few seconds.

One potential source of readout error comes from the large size of the overall memory bank, where the parasitic capacitances in the wiring could cause charge sharing issues during readout that decrease the dynamic range and SNR. To reduce charge sharing effects, the ROIC has voltage buffers in the readout paths. Adding buffers to every single memory cell would have cost too much area and power, so output buffers are instead shared by sets of 64 memory cells.

The memory can be used in groups of 1, 4, 8, or 16 cells per sample, yielding a storage capacity of 768, 192, 96, or 48 frames. In addition to reducing charge sharing effects, grouped memory cells can also improve the kTC noise. However, at 77° K, the 1/f noise is comparable to the kTC noise, and thus improvements from combining memory cells can be marginal. Before its output from the ROIC, the readout signal is buffered to fully differential to suppress interference and ground loops between the cryostat and the data acquisition system.

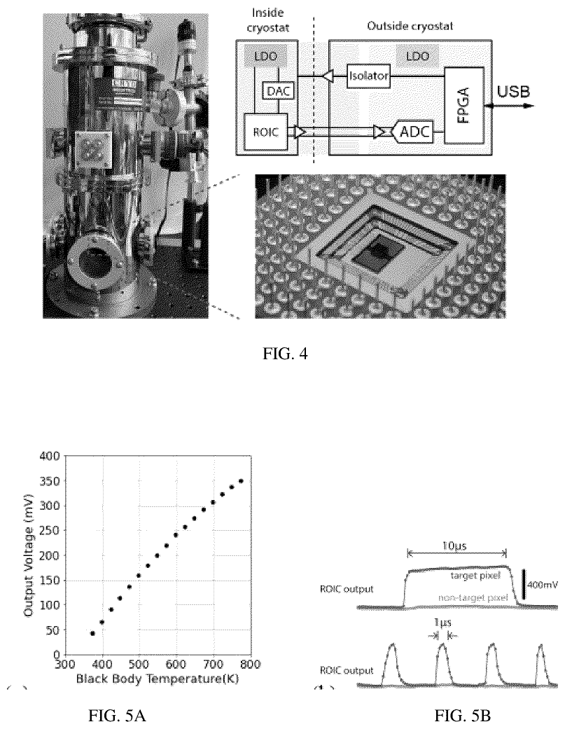

In FIG. 4, an exemplary experimental cryostat setup is illustrated. Inside a liquid nitrogen cryostat, the FPA+ROIC detector assembly is mounted behind an optical window. Outside the cryostat is an accompanying data acquisition board with an ADC and FPGA.

The ROIC has a total area of 26 mm², and at its peak activity level it dissipates 0.25 W while bursting at five million frames per second. The 24×24 pixel array has a pitch of 30 μm and occupies 0.54 mm², while the large memory banks occupy 18.7 mm². The FPA is indium bump-bonded to the ROIC, and the ROIC is wire-bonded to a ceramic pin grid array (CPGA) package in a cavity-down configuration.

The backside of the ceramic package is placed in contact with the cold finger of the liquid nitrogen cryostat. A cold shield is also positioned around the detector, reducing the background thermal noise from the directions other than the cryostat's optical window. The assembly is mounted on the backside of a circuit board inside the cryostat, with an opening for optical access. Power, control, and signal lines are routed out of the vacuum chamber through custom cables. Outside the cryostat, a room-temperature data acquisition board hosts an ADC and FPGA with an USB 3.0 interface. System control and acquisition are managed through a Python environment. With a readout speed of 250 000 samples/sec, the full burst frame bank can be digitized in less than 1.8 s. At 77° K, the measured memory cell leakage over this time is <0.01% FS.

FIG. 5A is an exemplary graph illustrating temperature sensitivity of one pixel, measured with a black-body source. FIG. 5B illustrates experimental responses to transient 1-10 μs optical pulses from a TTL-modulated infrared laser diode.

The ROIC has an analog conversion gain of 0.21 μV/e and a maximum capacity of 2800 ke. In FIG. 5A, we characterized the image sensor's temperature response with an infrared black-body reference, with a target emissivity of 0.95. A liquid-cooled aperture was installed in front of the target, and the temperature of the target ranged from 100° C. to 500° C., corresponding to 3.75-7.77 μm peak emission wavelengths. It is worth noting that the exact curvature of the response is a complex function of the focusing optics and detector responsivity, and these measurements were made with a simple two-lens configuration that was not optimized for chromatic aberration.

A first experimental demonstration of high-speed transient IR capture is presented in FIG. 5B. An infrared laser diode was modulated with TTL logic, while the ROIC performed a burst acquisition at 5 m frames per second. The measured turn-on time of the laser pulse is less than 1 μs, and the system can easily resolve optical pulses between 10 and 1 μs.

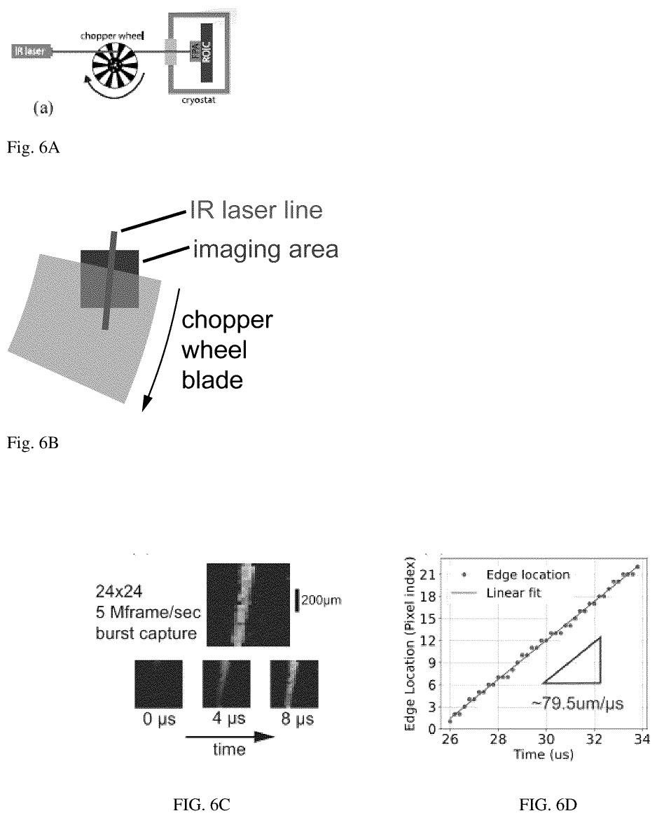

FIGS. 6A and 6B illustrate spatio-temporal infrared imaging at five million frames per second. A chopper wheel was spinning at 200 cycles/sec, periodically revealing an IR laser line on the imager. In FIG. 6C, image frames before and after the laser line was revealed. In FIG. 6D, leading edge of the revealed laser line was moving at 79.5 μm/μs.

We pointed a static line-profile IR laser module at the FPA through the cryostat window, and modulated the light path with an optical chopper. With the chopper rotating at 200 Hz, the 2.5-inch radius blades are expected to be traveling at 79.8 μm/μs. Burst image sequences measured the IR laser line emerging from behind the chopper blade at 79.5 μm/μs.

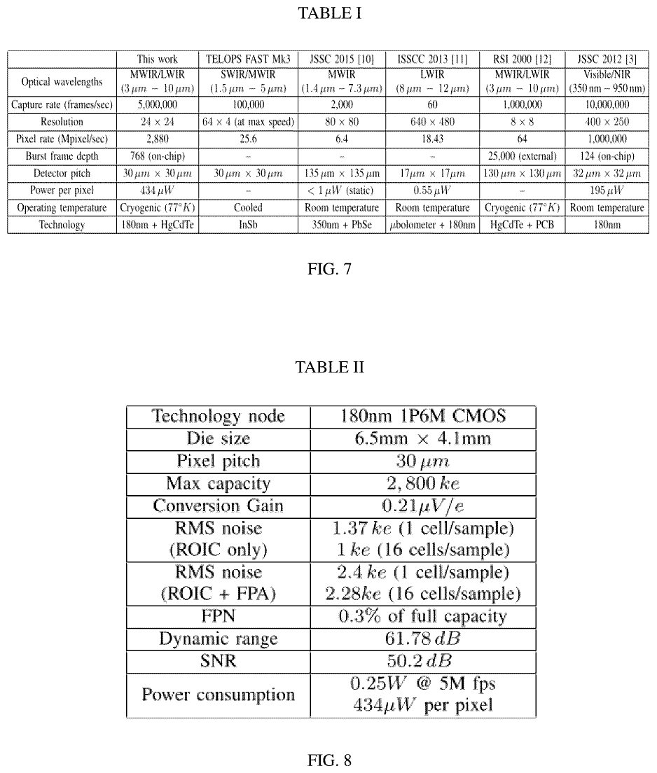

A comparison with state-of-the-art high-speed IR imagers is shown in Table I in FIG. 7, and a performance summary is shown in Table II in FIG. 8. This work is the fastest demonstrated MWIR/LWIR imaging array, with a uniquely designed burst-capture CMOS ROIC co-located with a cryogenic FPA. Extending MWIR/LWIR thermal imaging to MHz frame rates with this high-speed infrared detector and its custom ROIC offers new opportunities to understand forces at the microscale and to design new materials.

In summary, the high-speed global-shutter thermal imaging system with 24V×24H resolution supports burst capture of up to 768 frames at up to five million frames per second.

### Example II

### Burst-Mode Cryogenic Thermal Imager Readout Integrated Circuit with Spatial and Temporal Compression

According to one aspect, a thermal imaging system is provided with a focal plane array bonded to a second embodiment of a custom CMOS read out integrated circuit (ROIC) utilizing spatial and temporal compression each of which are within a cryostat and placed behind an optical window through which infrared laser light is to be transmitted. According to one aspect, the second embodiment of a CMOS custom read out integrated circuit includes architecture for high-speed burst-mode thermal imaging, with a larger detector array and an architecture that supports real-time spatial or temporal compressive sensing to increase the number of frames that can fit in the on-chip memory bank. According to one aspect, photocurrent is buffered in a pixel and stays as a current signal which is not integrated until it reaches a memory cell.

For ease of understanding, discussion of a ROIC in this section refers to an embodiment of an ROIC with architecture that supports real-time spatial or temporal compressive sensing.

As is known in the art, compressed sensing (CS) is a signal processing technique that enables reconstruction of a sparse signal from a reduced number of measurements. When the sparse signal X is sparse in some domain, it can be compressed with a matrix Φ. Assuming the target signal X∈RN is sparse, the measurement process can be expressed by the equation Y=ΦX, where Φ∈R^{M×N} is the compression matrix. M samples are stored instead of N, where M<N. Y E R^{M} is the set of measurements taken, which is compressed because M<N. The reconstruction of the signal X from the measurements Y can by formulated as a constrained optimization problem:

min∥X′∥ₚ, s subject to ΦX′=X

where p is often set to 0 or 1, determining whether the sparsity of vector X′ is measured by its l₀-norm (the sum of non-zero entries) or by its l₁-norm (the sum of the absolute value of each entry). The total variation (tυ)-norm can also be a better option when the signal is piecewise smooth, as it is more likely to preserve features such as edges.

Compressive sensing has been applied in visible light imaging to speed up frame rates, reduce power consumption, improve depth sensing, or extend dynamic range. Compressive sensing has also been used towards super-resolution applications both in infrared imaging and THz imaging. Compressive sensing has also been used in ultra high speed burst-mode visible light image sensors that reach millions of frames per second, by combining multiple optical apertures arrayed across a sensor or by implementing macro-pixels with several local charge storage sites per photodiode.

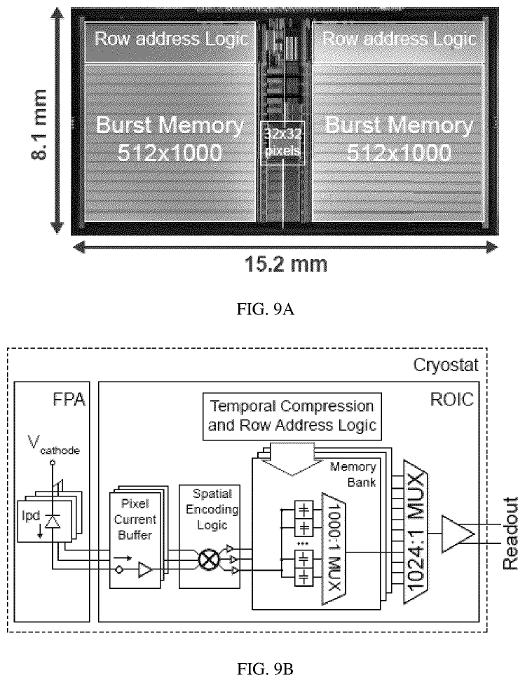

FIG. 9A illustrates an exemplary die photo of the custom cryogenic CMOS ROIC for infrared imaging. The die has a total area of 123.3 mm², and at its peak activity level dissipates 0.54 W while bursting at 5 million frames/second. The die includes row address logic modules, burst-memory banks. The ROIC is bonded (e.g. bump bonded0 to an infrared focal plane array detector (FPA). The FPA may have a 32^{V}×32^{H} pixel array at a 30-micron pitch in a common-cathode arrangement. The pixel pitch is close to the diffraction-limited resolution for the Long-Wave Infrared (LWIR) focusing optics. The photocurrent from each pixel is independently buffered and steered into large on chip burst-frame memory banks. In some instances, the FPA may be a mercury cadmium telluride (HgCdTe) photodiode array. HgCdTe photodetectors provide a small bandgap and have excellent infrared sensitivity.

The burst-memory banks may be implemented as a series of capacitor banks. The die may contain more than 1 million memory cells plus switches and logic. Each cell may occupy 6 μm×9.46 μm, and may have a Cmem=68.5 fF. It is possible to reduce noise by writing to multiple cells at one time, trading off burst length. Without compression enabled, current signals are integrated onto individual capacitors within the burst-memory banks. When image compression logic is enabled, the current signals from multiple pixels (spatial compression) or from multiple time points (temporal compression) may end up steered into the same memory capacitor and summed in the charge domain. The row address logic may control the steering and storage of the current signals. In some instances, only one compression mode may be enabled at one time. The burst-memory banks may be written to in parallel at up to 5 million frames/second.

After the burst of data is captured, the burst-memory bank is read out serially and digitized at reduced speed. Operating at very low temperature within the cryostat may significantly reduce charge leakage from the burst-memory banks during the readout process. In some instances, the burst-memory banks should be read out in the millisecond following a burst capture to avoid compromising the dynamic range.

One potential source of readout error comes from the large size of the overall memory bank, where the parasitic capacitances in the wiring could cause charge sharing issues during readout that decrease the dynamic range and SNR. To reduce charge sharing effects, the ROIC may have voltage buffers in the readout paths. According to one aspect, output buffers are shared sets of 64 memory cells.

FIG. 9B illustrates in schematic an architectural diagram of the signal paths within the thermal imager supporting high speed burst imaging. The FPA may receive inputs to generate photocurrents for pixels. Each individual pixel may then be communicated to the ROIC. Each pixel of the ROIC may be acquired with a high-speed buffered direct injection (BDI) circuit, which buffers the photocurrent during the brief exposure time and regulates the photodiode anode to maintain a constant reverse bias (typically 50 mV). The hybrid FPA/ROIC assembly can achieve a high optical fill factor while still having area within each pixel for signal conditioning circuits. The BDI current buffer may have a bandwidth >136 MHz and consumes 55 μW.

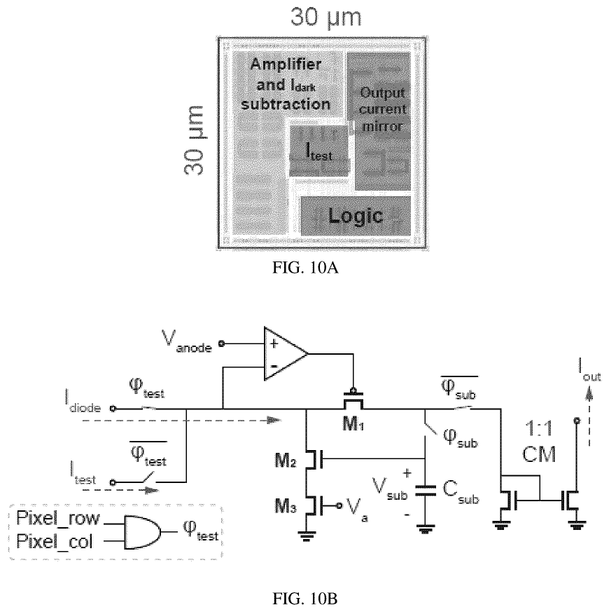

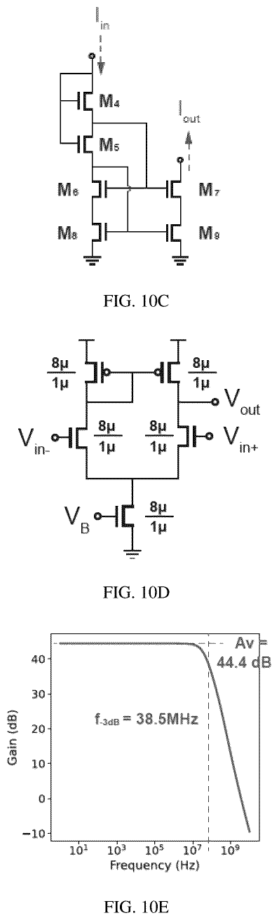

FIGS. 10A-10E illustrate exemplary diagrams of an embodiment of the ROIC. FIG. 10A shows an exemplary pixel cell layout according to one embodiment. Each pixel in the ROIC includes a buffered direct injection (BDI) circuit with dark current subtraction, a test current injection circuit, a current mirror for output, and a logic circuit. The BDI circuit may provide high injection efficiency over low-resistance photodiodes. The BDI circuit may perform dark current subtraction, where it “memorizes” the experimental dark current in each pixel in the moments before the signal acquisition, to help mitigate the reverse leakage current. The system is designed to acquire burst videos of brief transient high-temperature events, and thus the time shortly before the burst capture can provide a useful quiescent background.

Each pixel additionally includes a test current injection circuit, in which external test currents can be mirrored to any of the pixels through a globally programmable scaling factor. The test current injection circuit may provide pulsed signals to subset of pixels on the chip. The pixel selection may be an AND of the pixel array's row and column logic. The test current injection circuit may provide both continuous and pulsed current signals to subsets of pixels on the chip.

HgCdTe photodiodes can have excellent responsivity in the infrared, but they can also suffer from low dynamic resistance and high reverse leakage. According to one aspect, a design of the pixels' readout circuits is shown in FIG. 10B. In the moments before burst image capture, the current is directed to charge up C_{sub}=940 fF until all the pixel current flows through M₂. M₃ is maintained in the linear region, serving as a degeneration resistance on M₂, and the bias value of Vₐ tunes the subtraction current range. During burst imaging, V_{sub} maintains its charge, subtracting the constant initial current value from the captured signal. The pixel circuit produces an output current which will later be integrated within the memory banks.

FIG. 10C shows an example current mirror of the pixel cell. A 1:1 current mirror may be used to buffer the output current from each pixel. Due to the channel length modulation effect, the copy current from the current mirror can vary significantly depending on different voltage loads. To eliminate drain voltage difference between M₈ and M₉, a cascoded structure is used to isolate the output voltage to the mirroring MOSFETs and provide higher accuracy. A self-biased structure is implemented to provide the level-shifting and accomplish the low-voltage design. M₅ is pushed into the linear region and acts as a resistor to raise the gate voltage M₆ and M₇.

FIG. 10D shows a schematic of an example amplifier user for the BDI structure. A simple differential pair is used to provide high injection efficiency over low-resistance photodiodes, like HgCdTe. As shown in FIG. 10E, the gain is 44.44 dB and the bandwidth is 38.4 MHz, with an injection efficiency of 0.9947.

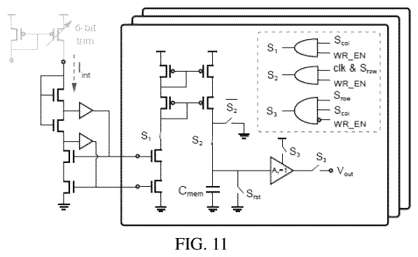

FIG. 11 shows an embodiment of an example memory cell. The on-chip memory is implemented as a series of capacitor banks. Each pixel has 1000 cells available and has its own local mirror and integration capacitor. The chip contains more than 1 million memory cells, thus area is a major design constraint of the memory bank. For example, in some instances, each memory cell occupies 6 μm×9.46 μm after layout optimization. To further improve area efficiency, the memory cell layout is grouped as a 2×2 block to save area by sharing body biases and wirings.

Each pixel's output current is buffered and fans out to all memory cells. Integration happens within each memory cell, controlled by addressing logic. Before fanning out into the memory bank, the pixel output current passes through a 6-bit programmable current gain stage. The gate voltages from the main branch are buffered and drive all memory cells at the same time.

S₁ is a gated column enable signal. In uncompressed capture and temporal compression modes, all columns are written in parallel. In spatial compression mode, the column-wise enable signal S₁ is enabled for only half of the columns at a time, doubling the burst duration. The row-wise address logic controls the switch S₂ to enable integration onto Cₘₑₘ. The mirror branch is connected to the ground to prevent voltage build-up when S₂ is open. S₂ includes a dummy switch to reduce charge injection. S₃ controls the readout path source follower and the connection to the output, which only turns on when the memory cell is selected during the readout phase.

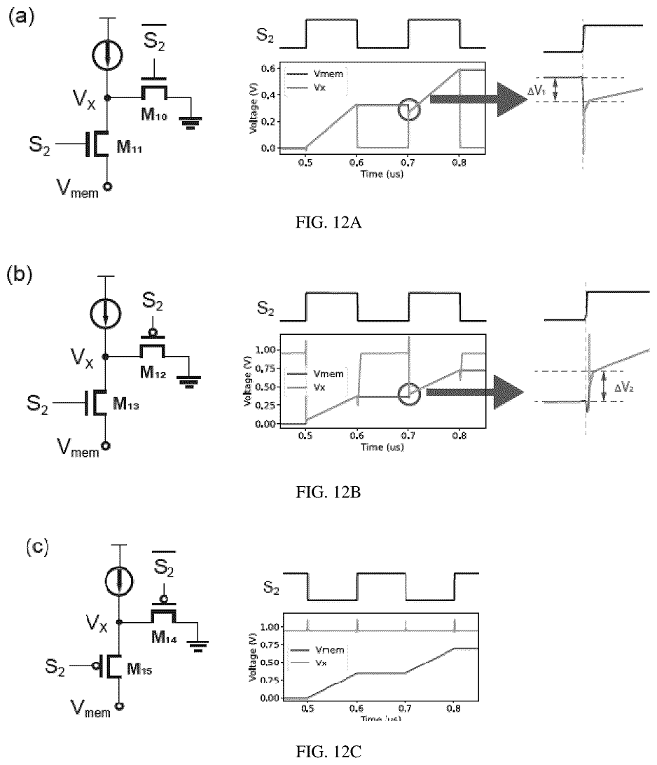

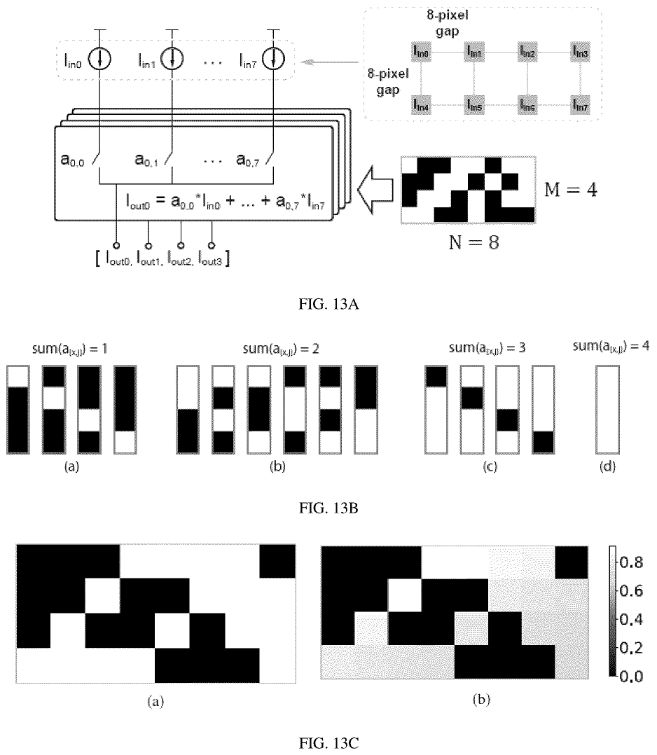

FIGS. 12A-12C show the possible combinations for the S₂ switch pair of the memory structure shown in FIG. 11. FIG. 12A and FIG. 12B both exhibit charge sharing issues, and charge sharing causes Vₘₑₘ to change every time that S₂ turns on. Given that S₂ switch pair in each memory cell toggles multiple times during temporal compression, these charge-sharing effects make both configurations unsuitable.

In contrast, the configuration of 12C utilizes PMOS transistors for both M₁₄ and M₁₅ with Vx serving as the source voltage for both switches. Due to constant current flow, Vx remains stable during both switching phases, ensuring uniform gate-source voltages, and Vₘₑₘ is decoupled from Vx and operates independently as the drain voltage. Because of the presence of body leakage current from using PMOS switches, the memory bank should be quickly read out in the milliseconds following a burst capture to avoid compromising the dynamic range.

### Spatial Compression Implementation

Most memory cells from a single frame are wasted to store a signal of near zero where a sparse 2D signal occupies only a few signals. Spatial compression improves storage efficiency by “reusing” the wasted memory cells without losing any data and recording longer at the same time. Spatial compression is implemented by encoding and duplicating the buffered current before it reaches the memory bank. The 32×32 pixel array is divided into 8×8-pixel tiles. Referring to FIG. 13A, 8 pixels from different tiles are compressed into 4 memory cells. The pixel current is mirrored and duplicated before encoding. Grouping non-adjacent pixels decreases their correlation, and 8:4 compression doubles the effective recording length. By reducing the number of stored signals by half, the system can record twice the burst frame duration using the same amount of memory.

Each binary entry a_{i,j} from the spatial compression matrix controls a switch, enabling the addition of the input current. Each output current is a unique combination of the 8 input signals, and then later given to the memory bank. A switching circuit is turned on when spatial compression is enabled, such that each current output signal has access to two rows of memory cells.

With the current mirror configuration, the size of the circuit is on the order of (M×N). In addition, all pixels of the global shutter image sensor record in parallel. As a result, it is not feasible to include all pixels with a single compression matrix, and instead, the 1024 pixels are divided into 128 groups of 8 pixels. The pixels in each group are not contiguous in the array, but instead sub-sampled from the same relative position in a 2×4 tiling of 8×8-pixel blocks. Compressing non-adjacent pixels increases the expected signal sparsity within each group. The spatial compression can be expressed as:

$$[ \begin{matrix}{I}_{out 0} \\ {I}_{out 1} \\ {I}_{out 2} \\ {I}_{out 3}\end{matrix} ] = [ \begin{matrix}{a}_{0 , 0} & {a}_{0 , 1} & ⋯ & {a}_{0 , 7} \\ {a}_{1 , 0} & {a}_{1 , 1} & ⋯ & {a}_{1 , 7} \\ ⋯ & ⋯ & & ⋯ \\ {a}_{3 , 0} & {a}_{3 , 1} & ⋯ & {a}_{3 , 7}\end{matrix} ] [ \begin{matrix}{I}_{in 0} \\ {I}_{in 1} \\ ⋯ \\ {I}_{in 7}\end{matrix} ]$$

where Iᵢₙᵢ is the pixel current, Iₒᵤₜᵢ is the current output to the memory bank, a_{i,j} are binary control bits. Given each memory cell has a known and identical integration time, assuming the same capacitor across all memories, the output current array is interchangeable with the voltage readings.

All 32 bits of the matrix are individually programmable through a scan chain. The matrix may be designed with unique columns to guarantee reconstruction for all 1-sparse signals, and also optimize the columns to have a 100% simulated success rate with all possible 2-sparse signals. Given the expected shape and direction of the shear band, the input signal is assumed to have a maximum sparsity of 2.

Because of the tiling pattern, the spatial information of the entire image is not fully preserved during compression. In rare cases, when two inputs are almost identical and no additional spatial information is available, reconstruction inaccuracies may occur. To address the inaccuracies, the matrix may be optimized such that for all possible combinations of two inputs from adjacent tiles (Iᵢₙₓ and I_{iny}) the combination of their corresponding columns (a_{|x|}+a_{|y|}) is unique. FIG. 13B shows all non-zero column. Picking 8 out of 16 columns gives C(16,8)/2−6435 possible combinations to form an 8-to-4 compression matrix, while only 42 satisfy the restriction mentioned above. Matrix (a) of FIG. 13C shows a sample matrix after optimization.

The layout of the current mirrors may be optimized with common-centroid placement and dummy devices to minimize device mismatch. Matrix (b) of FIG. 13C shows a sample matrix after introducing both vertical and horizontal gradients to simulate mismatch. The mismatch ratio is relative to process variation and the location of the encoding current mirrors. To mitigate these effects, every 8 compression encoders share the same matrix, such that independent matrices can be given based on local mismatch conditions.

### Temporal Compression Implementation

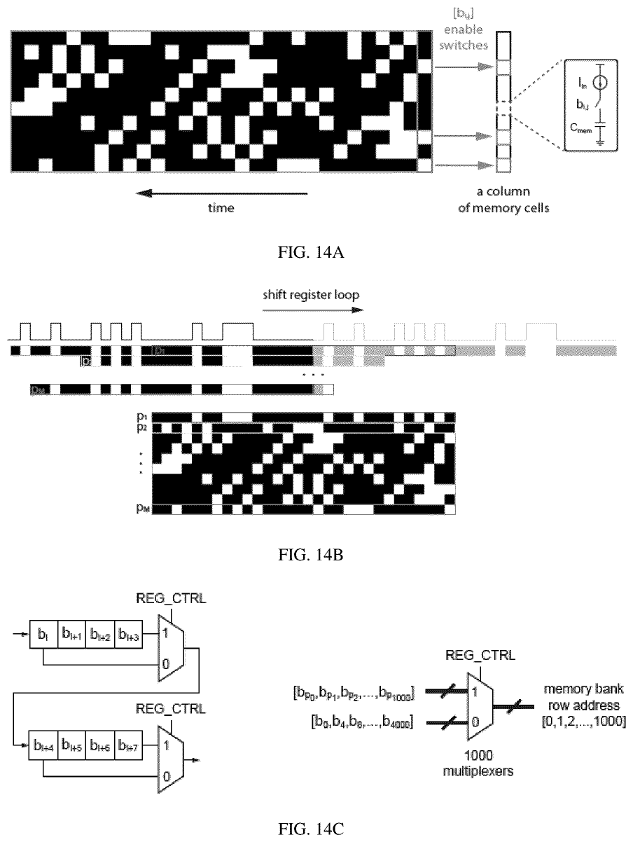

Compressive sensing can extend the recording length while sustaining the signals when a signal is temporally sparse. Regular recording sequentially enables one memory cell at a time. When temporal compression is enabled, multiple memory cells are integrating a signal at the same time in different combinations. Each column of the compression matrix assigns memory cells for that frame, enabling them to integrate the duplicated pixel current. The compression matrix may be a programmable switch matrix to enable encoding the current integration of the duplicated pixel current in each memory cell. Shown in FIGS. 14A and 14B, temporal compression logic is merged with the row-addressing circuits and encodes the current integration of each memory cell.

Mathematically, the size of the temporal compression matrix can be very large, but for hardware efficiency it is implemented as a random circulant matrix. While equally-spaced circulant matrices are easier to implement in hardware, random circulant matrices tend to have lower mutual coherence, are more likely to satisfy the restricted isometry property, and encode most signals as effectively as random Gaussian matrices. The circulant matrix is derived from a shift register loop which has a maximum length of 4000 bits and is initialized through the scan chain with a random bitstream. To implement this, the first row is randomly generated every time and stored in a shift register loop by the scan chain. Each subsequent row of the compression matrix has a different starting position in the loop. With the control sequence shifting one bit, the entire matrix shifts one column per frame during recording, as shown in FIG. 14B.

The compression process can be expressed as:

$$[ \begin{matrix}{I}_{int 0} \\ {I}_{int 1} \\ ⋯ \\ {I}_{intM}\end{matrix} ] = [ \begin{matrix}{b}_{0 , {p}_{0}} & ⋯ & {b}_{0 , N - {p}_{0}} \\ {b}_{0 , {p}_{1}} & ⋯ & {b}_{1 , N - {p}_{1}} \\ ⋯ & & ⋯ \\ {b}_{M , {p}_{M}} & ⋯ & {b}_{M , N - {p}_{M}}\end{matrix} ] [ \begin{matrix}{I}_{in 0} \\ {I}_{in 1} \\ ⋯ \\ {I}_{inN}\end{matrix} ]$$

where b_{i,j} is binary, M is the number of memory cells used, N is the recorded burst length, and [p₀, p₁, p₂, . . . , p_{M}] are the starting positions of each row. In some instances, to reduce complexity, two different sets of randomized [p₀, p₁, p₂, . . . , p_{M}] are used and alternated with a set of multiplexers. Instead of the l1-norm, to-norm may be used for temporal signal reconstruction. Gaussian pulses and square waves are simulated to optimize the reconstruction algorithms and find the optimal density for the compression matrix.

The shift register functions as the row addressing logic of the memory bank as shown in FIG. 14C. When temporal compression is enabled, REG_CTRL switches all multiplexers to 1, forming a 4000-bit shift register loop. The flip-flop outputs are routed through the synthesized nets to the shift pattern switching logic. The memory cells are accessed exclusively through the randomized pattern defined for compression. When REG_CTRL is disabled, all multiplexers are set to 0 to form a 1000-bit register loop. The shift register may be reset to [1, 0, 0, . . . 0], enabling sequential row-by-row access to the memory cells.

There may be a wide variation observed in the measurements that leads to distortion and mismatch in portions of the data. Some memory cells may exhibit small signals and low dynamic range, while others become saturated under the same conditions. To address device mismatch, memory cells may be combined for averaging. Rather than using the 1000-bit one-hot vector, a 125-bit vector may be cyclically repeated eight times to create eight copies of the same data sample. The effective frame rate is reduced from 1000 to 125, but the redundant copies allow for removal of distorted samples. Averaging the data can improve the measurement accuracy.

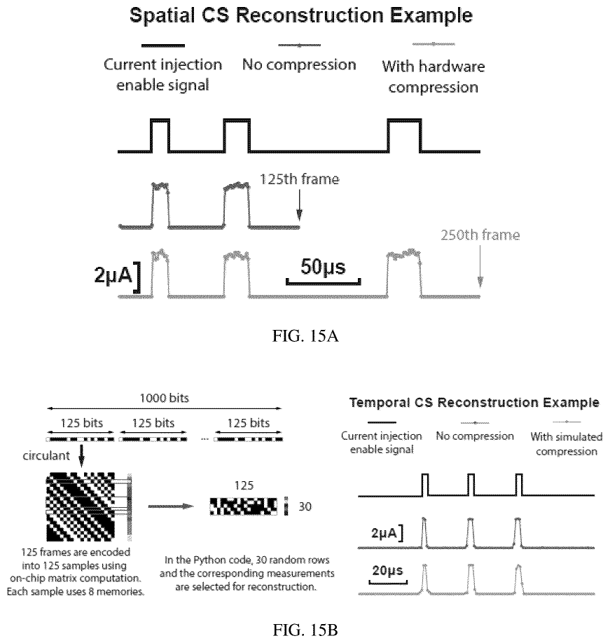

FIG. 15A shows an example spatial reconstruction. In some instances, when spatial compression is enabled, the recorded length may be doubled from 125 to 250 frames, and the system is able to capture the additional pulse near the 200-frame mark. The spatial compression results double recording length for 2× spatial compressions.

FIG. 15B shows an example temporal reconstruction. The temporal compression may produce a 4.1× compression. Reconstruction may be possible using fewer samples than recorded. During compression 125 frames are encoded into 125 samples with the circulant matrix using on-chip logic. After readout, 30 rows and their corresponding measurements are randomly selected for reconstruction. After reconstruction, all 125 frames may be recovered using only 30 out of the 125 measurements while ignoring the rest, achieving a compression ratio greater than 4:1. Smaller compression matrices may be applied.

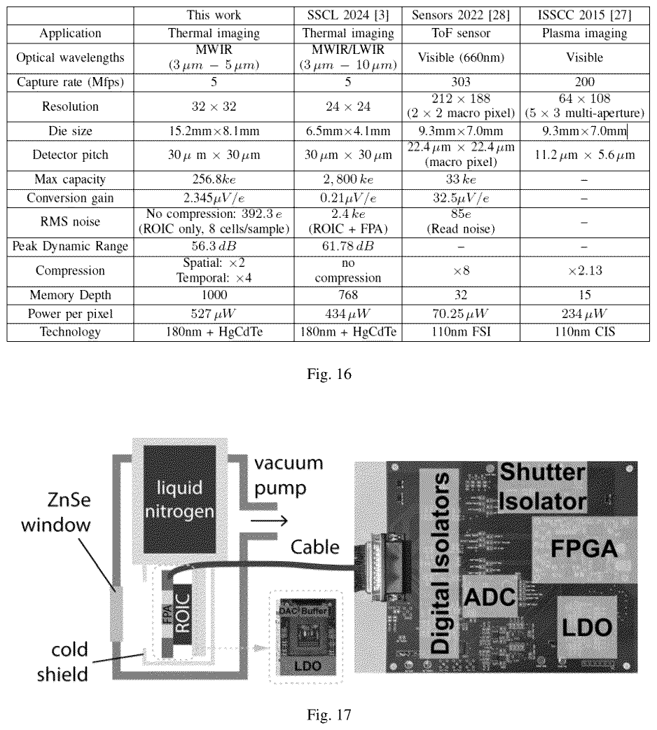

FIG. 16 shows a comparison of the thermal imaging system of the present disclosure compared with other state-of-the-art compressive sensing imagers. The high-speed global-shutter imager achieved thermal imaging for optical wavelengths in the MWIR with 32×32 resolution, supporting burst capture and spatial/temporal compression up to 5 million frames per second, and a memory of 1000 frames. The compared thermal imagers are related compressive sensing circuits but at different wavelengths. As demonstrated herein, the high-speed global-shutter thermal imaging system with 32×32 resolution supports burst capture of up to 1000 frames at up to five million frames per second using hardware enabled spatial and temporal compression logic.

FIG. 17 depicts an exemplary cryostat setup. Inside a liquid nitrogen cryostat, the ROIC assembly is mounted behind an optical window. Outside the cryostat is an accompanying data acquisition board with an analog to digital converter (“ADC”) and field programmable gate array (“FPGA”). The ROIC has a total area of 123.2 mm², and at its peak activity level, it dissipates 0.54 W while bursting a 5 million frames/second. The 32×32 pixel array has a 30 μm pitch and occupies 1.13 mm², while the large memory banks occupy 66.8 mm². The ROIC is wire-bonded to a ceramic pin grid array (CPGA) package in a cavity-down configuration as shown in FIG. 17, and the backside of the ceramic package is in contact with the cold finger of the liquid nitrogen cryostat. A cold shield around the detector reduces background thermal noise. The assembly is mounted on the backside of a circuit board in the cryostat, behind an optical window. Power, control, and signal lines are routed out of the vacuum chamber through custom cables. Outside the cryostat, a room-temperature data acquisition board hosts an ADC, FPGA, and USB 3.0 interface. System control and signal acquisition are implemented in Python.

### Example III

### EMBODIMENTS

The present disclosure provides a thermal imager including a focal plane array (FPA) including a plurality of pixel detectors, wherein each pixel detector has a corresponding pixel cell; a read-out integrated circuit (ROIC) bonded to the FPA, wherein the ROIC includes a burst-frame memory bank; a programmable switch matrix for performing temporal compression; and a spatial compression switch matrix for performing spatial compression. According to one aspect, the burst-frame memory bank includes a plurality of columns of memory cells; and wherein each pixel cell includes a current mirror configured to steer pixel signals to the plurality of columns of memory cells. According to one aspect, performing spatial compression includes summing pixel signals, by the spatial compression switch matrix, corresponding to a single frame time prior to being stored in the burst-frame memory bank. According to one aspect, performing temporal compression includes summing pixel signals, by the programmable switch matrix, corresponding to multiple frame times prior to being stored in the burst-frame memory bank. According to one aspect, the programmable switch matrix includes a shift register configured to determine which of the plurality of columns of memory cells are enabled during successive frame times. According to one aspect, the programmable switch matrix enables connections between each pixel cell and a plurality of columns of memory cells. According to one aspect, thermal imager further includes an optical window, wherein the FPA is positioned behind the optical window; and wherein the FPA is located within a cryostat comprising a store of coolant.

The present disclosure provides a thermal imaging system including a cryostat, the cryostat including a store of coolant and a detector assembly; wherein the detector assembly includes a focal plane array (FPA) including a plurality of pixel detectors, wherein each pixel detector has a corresponding pixel cell; a read-out integrated circuit (ROIC) bonded to the FPA, wherein the ROIC includes a burst-frame memory bank and a programmable switch matrix for performing temporal compression; and a spatial compression switch matrix for performing spatial compression. According to one aspect, the burst-frame memory bank includes a plurality of columns of memory cells; and wherein each pixel cell includes a current mirror configured to steer pixel signals to the plurality of columns of memory cells. According to one aspect, performing temporal compression includes summing pixel signals, by the programmable switch matrix, corresponding to multiple frame times prior to being stored in the burst-frame memory bank. According to one aspect, the programmable switch matrix includes a shift register configured to determine which of the plurality of columns of memory cells are enabled during successive frame times. According to one aspect, performing spatial compression includes summing pixel signals, by the spatial compression switch matrix, corresponding to a single frame time prior to being stored in the burst-frame memory bank. According to one aspect, the programmable switch matrix enables connections between each pixel cell and a plurality of columns of memory cells. According to one aspect, the thermal imaging system further includes an optical window; and wherein the FPA is positioned behind the optical window.

The present disclosure provides a method including receiving, via a focal plane array (FPA) including a plurality of pixel detectors, infrared light; generating, based on the infrared light, a plurality of pixel signals; processing, by a read-out integrated circuit (ROIC) bonded to the FPA, the plurality of pixel signals, wherein processing includes performing spatial compression on the pixel signals; storing, in a memory of the ROIC, the processed plurality of pixel signals, wherein storing includes performing temporal compression on the pixel signals; wherein performing spatial compression and performing temporal compression occur independently in time; and outputting, based on the stored plurality of pixel signals, a thermal image. According to one aspect, performing spatial compression includes summing, by a spatial compression matrix, the plurality of pixel signals corresponding to a single time frame prior to storing. According to one aspect, the ROIC includes a plurality of pixel cells each including a current mirror; and wherein storing includes steering, by each current mirror, the processed plurality of pixel cells to a plurality of columns of the memory. According to one aspect, performing temporal compression includes summing, by a programmable switch matrix, a portion of the plurality of pixel signals corresponding to multiple frame times prior to being stored in the memory. According to one aspect, the programmable switch matrix includes a shift register; and wherein performing temporal compression further includes enabling, by the shift register, a plurality of memory cells during successive frame times. According to one aspect, the method further includes enabling, by a programmable switch matrix, connections to a portion of the plurality of columns of the memory for performing temporal compression.

In the foregoing description, it will be readily appreciated by those skilled in the art that modifications may be made to the invention without departing from the concepts disclosed herein.

Such modifications are to be considered as included in the following claims, unless the claims by their language expressly state otherwise.

What is claimed is:

1. A thermal imager comprising:
a focal plane array (FPA) comprising a plurality of pixel detectors, wherein each pixel detector has a corresponding pixel cell;
a read-out integrated circuit (ROIC) bonded to the FPA, wherein the ROIC comprises:
a burst-frame memory bank;
a programmable switch matrix for performing temporal compression; and
a spatial compression switch matrix for performing spatial compression.

2. The thermal imager of claim 1, wherein the burst-frame memory bank comprises a plurality of columns of memory cells; and
wherein each pixel cell comprises a current mirror configured to steer pixel signals to the plurality of columns of memory cells.

3. The thermal imager of claim 2, wherein performing spatial compression comprises summing pixel signals, by the spatial compression switch matrix, corresponding to a single frame time prior to being stored in the burst-frame memory bank.

4. The thermal imager of claim 1, wherein performing temporal compression comprises summing pixel signals, by the programmable switch matrix, corresponding to multiple frame times prior to being stored in the burst-frame memory bank.

5. The thermal imager of claim 4, wherein the programmable switch matrix comprises a shift register configured to determine which of the plurality of columns of memory cells are enabled during successive frame times.

6. The thermal imager of claim 1, wherein the programmable switch matrix enables connections between each pixel cell and a plurality of columns of memory cells.

7. The thermal imager of claim 1, further comprises:
an optical window, wherein the FPA is positioned behind the optical window; and
wherein the FPA is located within a cryostat comprising a store of coolant.

8. A thermal imaging system comprising:
a cryostat, the cryostat comprising a store of coolant and a detector assembly;
wherein the detector assembly comprises:
a focal plane array (FPA) comprising a plurality of pixel detectors, wherein each pixel detector has a corresponding pixel cell;
a read-out integrated circuit (ROIC) bonded to the FPA, wherein the ROIC comprises a burst-frame memory bank and a programmable switch matrix for performing temporal compression; and
a spatial compression switch matrix for performing spatial compression.

9. The thermal imaging system of claim 8, wherein the burst-frame memory bank comprises a plurality of columns of memory cells; and
wherein each pixel cell comprises a current mirror configured to steer pixel signals to the plurality of columns of memory cells.

10. The thermal imaging system of claim 9, wherein performing temporal compression comprises summing pixel signals, by the programmable switch matrix, corresponding to multiple frame times prior to being stored in the burst-frame memory bank.

11. The thermal imaging system of claim 10, wherein the programmable switch matrix comprises a shift register configured to determine which of the plurality of columns of memory cells are enabled during successive frame times.

12. The thermal imaging system of claim 9, wherein performing spatial compression comprises summing pixel signals, by the spatial compression switch matrix, corresponding to a single frame time prior to being stored in the burst-frame memory bank.

13. The thermal imaging system of claim 8, wherein the programmable switch matrix enables connections between each pixel cell and a plurality of columns of memory cells.

14. The thermal imaging system of claim 8, further comprising an optical window; and
wherein the FPA is positioned behind the optical window.

15. A method comprising:
receiving, via a focal plane array (FPA) comprising a plurality of pixel detectors, infrared light;
generating, based on the infrared light, a plurality of pixel signals;
processing, by a read-out integrated circuit (ROIC) bonded to the FPA, the plurality of pixel signals, wherein processing comprises performing spatial compression on the pixel signals;
storing, in a memory of the ROIC, the processed plurality of pixel signals, wherein storing comprises performing temporal compression on the pixel signals;
wherein performing spatial compression and performing temporal compression occur independently in time; and
outputting, based on the stored plurality of pixel signals, a thermal image.

16. The method of claim 15, wherein performing spatial compression comprises summing, by a spatial compression matrix, the plurality of pixel signals corresponding to a single time frame prior to storing.

17. The method of claim 16, wherein the ROIC comprises a plurality of pixel cells each comprising a current mirror; and
wherein storing comprises steering, by each current mirror, the processed plurality of pixel cells to a plurality of columns of the memory.

18. The method of claim 15, wherein performing temporal compression comprises summing, by a programmable switch matrix, a portion of the plurality of pixel signals corresponding to multiple frame times prior to being stored in the memory.

19. The method of claim 18, wherein the programmable switch matrix comprises a shift register, and
wherein performing temporal compression further comprises enabling by the shift register, a plurality of memory cells during successive frame times.

20. The method of claim 15, further comprising:
enabling, by a programmable switch matrix, connections to a portion of the plurality of columns of the memory for performing temporal compression.
